(19) United States
(12) Patent Application Publication
(10) Pub. No.: US 2022/0223441 A1
(43) Pub. Date: Jul. 14, 2022

(54) PROCESS CONDITION SENSING APPARATUS

(71) Applicant: KLA Corporation, Milpitas, CA (US)

(72) Inventor: Farhat A. Quli, Castro Valley, CA (US)

(73) Assignee: KLA Corporation, Milpitas, CA (US)

(21) Appl. No.: 17/147,171

(22) Filed: Jan. 12, 2021

Related U.S. Application Data
(60) Provisional application No. 63/135,012, filed on Jan. 8, 2021.

(51) Int. Cl. H01L 21/67; H05K 5/02; H05K 5/00; G05B 19/418

(52) U.S. Cl. CPC H01L 21/67253; H05K 5/0239; G05B 2219/37216; H05K 5/0226; G05B 19/41805; H05K 5/0091

(57) ABSTRACT

An enclosure assembly is disclosed, in accordance with one or more embodiment of the present disclosure. The enclosure assembly includes a top portion. The enclosure assembly further includes a bottom portion. The top portion is detachably connectable to the bottom portion via one or more coupling devices. The top portion is further reversibly, electrically couplable to the bottom portion via one or more electronic contacts. One or more electronic components are disposed within the enclosure assembly.

### CROSS-REFERENCE TO RELATED APPLICATIONS

The present application claims the benefit under 35 U.S.C. § 119(e) of U.S. Provisional Application Ser. No. 63/135,012 filed Jan. 8, 2021, entitled PROCESS CONDITION SENSING APPARATUS, naming Farhat Quli as inventor, which is incorporated herein by reference in the entirety.

### TECHNICAL FIELD

The present invention generally relates to process condition sensing apparatuses, and, more particularly, to extending the viable operating conditions of process condition sensing apparatuses.

### BACKGROUND

As the demand for improved process monitoring systems continues to increase, the tolerances on process conditions in semiconductor device processing environments continue to decrease. Thermal uniformity within a processing system is one such condition. In a device that is intended to measure temperature the electronics and/or batteries can be designed to be insulated by a thermal mass and never reach above a certain temperature. If either the electronics or battery are exposed to a temperature that exceeds a certain temperature some electronics and/or battery become permanently damaged and non-functional, while other electronics may continue to function above this temperature. Thus, the system has to be removed from the thermal environment before this temperature is achieved to prevent the electronics and/or battery from becoming permanently damages and non-functional. However, even if the electronics and/or battery are insulated by a thermal mass, the electronics and/or battery will eventually become too hot. In some cases, the performance of the electronics and/or battery degrade rapidly after a certain temperature is reached, resulting in high current draw, loss of measurement fidelity, and the like. These current methods are unable to monitor temperature under the extreme conditions (e.g., high temperature) required of current processing techniques without contaminating the associated chamber. Further, the current methods do not achieve sufficient time at temperature to provide value for all potential use cases.

Therefore, it would be desirable to provide an apparatus and method that cure the shortfalls of the previous approaches identified above.

### SUMMARY

A process condition sensing apparatus is disclosed, in accordance with one or more embodiments of the present disclosure. In one embodiment, the apparatus includes a substrate. In another embodiment, the apparatus includes an electronic assembly including one or more electronic components. In another embodiment, the apparatus includes an enclosure assembly comprising a top portion and a bottom portion, the top portion being detachably connectable to the bottom portion via one or more coupling devices, the top portion being reversibly, electrically couplable to the bottom portion via one or more electronic contacts, the one or more electronic components of the electronic assembly being disposed within the enclosure assembly. In another embodiment, the apparatus includes a sensor assembly communicatively coupled to the electronic assembly, the sensor assembly including one or more sensors disposed on the substrate at one or more locations across the substrate, the one or more sensors being configured to acquire one or more measurement parameters at the one or more locations across the substrate.

An enclosure assembly is disclosed, in accordance with one or more embodiment of the present disclosure. In one embodiment, the enclosure assembly includes a top portion. In another embodiment, the enclosure assembly includes a bottom portion, the top portion being detachably connectable to the bottom portion via one or more coupling devices, the top portion being reversibly, electrically couplable to the bottom portion via one or more electronic contacts, one or more electronic components of the electronic assembly being disposed within the enclosure assembly.

A process condition sensing apparatus is disclosed, in accordance with one or more embodiments of the present disclosure. In one embodiment, the apparatus includes a substrate. In another embodiment, the apparatus includes an electronic assembly including one or more electronic components, the one or more electronic components comprising: one or more processors, communication circuitry, memory, and a power source. In another embodiment, the apparatus includes an enclosure assembly comprising a top portion and a bottom portion, the top portion being detachably connectable to the bottom portion via one or more coupling devices, the top portion being reversibly, electrically couplable to the bottom portion via one or more electronic contacts, the one or more electronic components of the electronic assembly being disposed within the enclosure assembly. In another embodiment, the apparatus includes a sensor assembly communicatively coupled to the electronic assembly, the sensor assembly including one or more sensors disposed on the substrate at one or more locations across the substrate, the one or more sensors being configured to acquire one or more measurement parameters at the one or more locations across the substrate, the one or more processors being configured to receive the one or more measurement parameters from the one or more sensors, the one or more processors being configured to stop receiving the one or more measurement parameters from the one or more sensors at a determined time.

A method is disclosed, in accordance with one or more embodiments of the present disclosure. In one embodiment, the method includes acquiring one or more measurement parameters using one or more sensors disposed on a substrate at one or more locations across the substrate. In another embodiment, the method includes receiving the one or more measurement parameters from the one or more sensors using one or more electronic components of an electronic assembly within an enclosure assembly, the enclosure assembly comprising a top portion and a bottom portion, the top portion being detachably connectable to the bottom portion via one or more coupling devices, the top portion being reversibly, electrically couplable to the bottom portion via one or more electronic contacts. In another embodiment, the method includes generating one or more control signals at a determined time to switch the operating conditions of the one or more electronic components of the electronic assembly, after the determined time the one or more electronic components of the electronic assembly stop receiving the one or more measurement parameters from the one or more sensors.

It is to be understood that both the foregoing general description and the following detailed description are exemplary and explanatory only and are not necessarily restrictive of the invention as claimed. The accompanying drawings, which are incorporated in and constitute a part of the specification, illustrate embodiments of the invention and together with the general description, serve to explain the principles of the invention.

### BRIEF DESCRIPTION OF THE DRAWINGS

The numerous advantages of the disclosure may be better understood by those skilled in the art by reference to the accompanying figures in which:

FIG. 1 illustrates a simplified cross-sectional view of a process condition sensing apparatus, in accordance with one or more embodiments of the present disclosure.

FIG. 2A illustrates a simplified cross-sectional view of an enclosure assembly of the process condition sensing apparatus in a closed state, in accordance with one or more embodiments of the present disclosure.

FIG. 2B illustrates a simplified exploded cross-sectional view of the enclosure assembly of the process condition sensing apparatus, in accordance with one or more embodiments of the present disclosure.

FIG. 2C illustrates a simplified exploded cross-sectional view of the enclosure assembly of the process condition sensing apparatus, in accordance with one or more embodiments of the present disclosure.

FIG. 3A illustrates a simplified cross-sectional view of an enclosure assembly of the process condition sensing apparatus in a closed state, in accordance with one or more embodiments of the present disclosure.

FIG. 3B illustrates a simplified exploded cross-sectional view of the enclosure assembly of the process condition sensing apparatus, in accordance with one or more embodiments of the present disclosure.

FIG. 3C illustrates a simplified exploded cross-sectional view of the enclosure assembly of the process condition sensing apparatus, in accordance with one or more embodiments of the present disclosure.

FIG. 4A illustrates a simplified rear view of the enclosure assembly of the processing condition sensing apparatus, in accordance with one or more embodiments of the present disclosure.

FIG. 4B illustrates a simplified side view of the enclosure assembly of the processing condition sensing apparatus, in accordance with one or more embodiments of the present disclosure.

FIG. 5 illustrates a simplified top view of the electronic assembly contained within the enclosure assembly, in accordance with one or more embodiments of the present disclosure.

FIG. 6 illustrates a simplified block diagram of one or more electronic components of the electronic assembly, in accordance with one or more embodiments of the present disclosure.

FIG. 7 is a time-temperature graph illustrating data collection of the process condition sensing apparatus, in accordance with one or more embodiments of the present disclosure.

FIG. 8 illustrates a flowchart depicting a method for extending the operating parameters of the process condition sensing apparatus, in accordance with one or more embodiments of the present disclosure.

### DETAILED DESCRIPTION

The present disclosure has been particularly shown and described with respect to certain embodiments and specific features thereof. The embodiments set forth herein are taken to be illustrative rather than limiting. It should be readily apparent to those of ordinary skill in the art that various changes and modifications in form and detail may be made without departing from the spirit and scope of the disclosure.

Reference will now be made in detail to the subject matter disclosed, which is illustrated in the accompanying drawings.

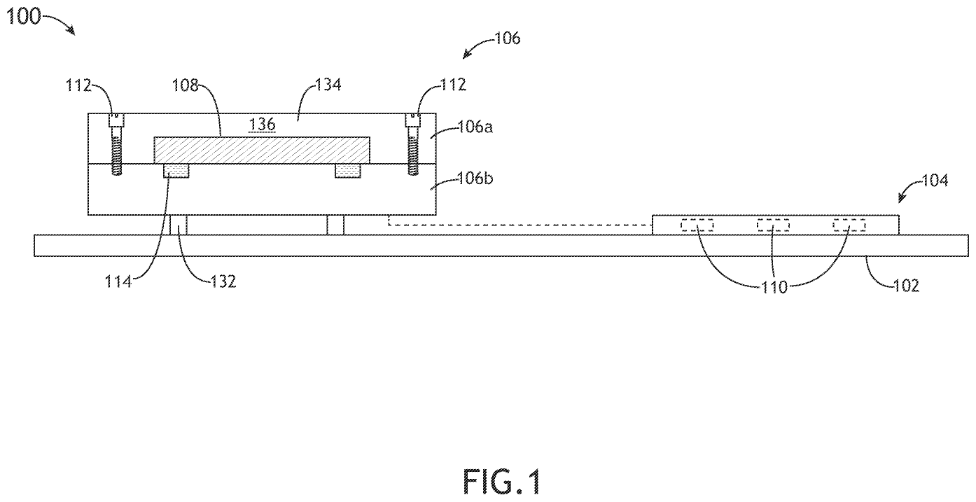

Referring generally to FIGS. 1-8, a process condition sensing apparatus and method is described, in accordance with one or more embodiments of the present disclosure.

Embodiments of the present disclosure are directed to a process condition sensing apparatus including a removable electronic assembly for use in high-temperature process applications. For example, the process condition sensing apparatus may include an enclosure assembly including a top portion configured to detachably connect to a bottom portion and further configured to reversibly, electrically couple to the bottom portion, such that one or more electronic components of the electronic assembly within the enclosure assembly may be removed and/or replaced if the one or more electronic components are damaged. In this regard, one or more electronic components of the electronic assembly may be easily replaced if an electronic component (e.g., battery, processor, memory, or the like) of the one or more electronic components encounters too high of a temperature, thereby extending the operating parameters (e.g., time and/or temperature) of the process condition sensing apparatus. Further, embodiments of the present disclosure are directed to a method for switching the operating mode of the process condition sensing apparatus. For example, the process condition sensing apparatus may be configured to stop receiving measurement data from the sensor assembly at a determined time or cease other functions, thereby extending the operating parameters of the process condition sensing apparatus.

Process condition sensing apparatuses may use an instrumented substrate to measure processing conditions within a processing chamber. These apparatuses provide the most accurate measure of the conditions of the chamber because the thermal conductivity of the substrate is the same as the actual semiconductor devices that will be processed. Process condition sensing apparatuses are generally described in U.S. Pat. No. 8,033,190, issued on Oct. 11, 2011 to Renken et al.; U.S. Pat. No. 8,604,361, issued on Dec. 10, 2013 to Sun et al.; U.S. Pat. No. 9,719,867, issued on Aug. 1, 2017 to Sharratt et al.; U.S. Pat. No. 9,823,121, issued on Nov. 21, 2017 to Sun et al.; U.S. Pat. No. 10,460,966, issued on Oct. 29, 2019 to Sun et al.; U.S. Patent Publication No. 2017/0219437, published on Aug. 3, 2017; and U.S. Patent Publication No. 2019/0368944, published on Dec. 5, 2019, which are each herein incorporated by reference in their entirety.

FIG. 1 illustrates a simplified cross-sectional view of the process condition sensing apparatus 100, in accordance with one or more embodiments of the present disclosure. In one embodiment, the apparatus 100 includes a substrate 102, a sensor assembly 104, an enclosure assembly 106, and an electronic assembly 108.

The substrate 102 may include any substrate known in the art of semiconductor processing. In one embodiment, the substrate 102 is a wafer. For example, the substrate 102 may include, but is not limited to, a semiconductor wafer (e.g., silicon wafer). The substrate 102 may be formed of any material known in the art including, but not limited to, silicon, glass, ceramic, gallium arsenide, carbide, nitride, quartz, or the like. It is noted herein that the substrate 102 may be the same size and shape as a standard substrate processed by a semiconductor device processing system. Further, it is noted herein that although FIG. 1 illustrates the substrate 102 without one or more layers, the apparatus 100 may include a layered substrate (e.g., a substrate with at least a top layer and a bottom layer) such that the one or more sensors 110 may be disposed within the one or more layers of the substrate 102. Therefore, the above discussion should not be construed as limiting the scope of the present disclosure.

In one embodiment, the substrate 102 is used to measure the processing conditions of semiconductor fabrication equipment, processing equipment, or the like. For example, the substrate 102 may be used to measure process conditions that a sample (e.g., a wafer) undergoes during processing. In another embodiment, the sensor assembly 104 includes one or more sensors 110 disposed on the substrate 102 at one or more locations across the substrate 102. In another embodiment, the one or more sensors 110 are configured to acquire one or more measurement parameters at the one or more locations across the substrate 102. It is noted herein that the sensor assembly 104 may include any configuration of sensors (e.g., number, location, etc.), therefore the configuration shown in FIG. 1 should not be construed as limiting the scope of the present disclosure.

It is noted that the one or more sensors 110 may include any measurement device known in the art including, but not limited to, one or more temperature sensors, one or more pressure sensors, one or more radiation sensors, one or more chemical sensors, or the like, or a combination thereof. For example, the one or more sensors 110 may include one or more temperature sensors configure to acquire one or more parameters indicative of temperature. For instance, the one or more temperature sensors may include, but are not limited to, one or more thermocouple (TC) devices (e.g., thermoelectric junction), one or more resistance temperature devices (RTDs) (e.g., thin film RTD), or the like. In another instance, in the case of pressure measurements, the one or more sensors 110 may include, but are not limited to, a piezoelectric sensor, a capacitive sensor, an optical sensor, a potentiometric sensor and the like. In another instance, in the case of radiation measurements, the one or more sensors 110 may include, but are not limited to, one or more light detectors (e.g., photovoltaic cell, photoresistor and the like) or other radiation detectors (e.g., solid state detector). In another instance, in the case of chemical measurements, the one or more sensors 110 may include, but are not limited to, one or more chemiresistors, gas sensors, pH sensors, and the like.

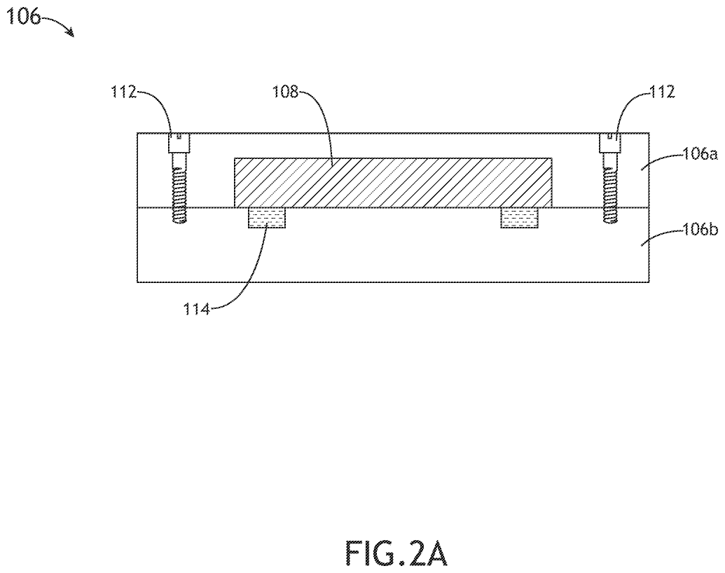

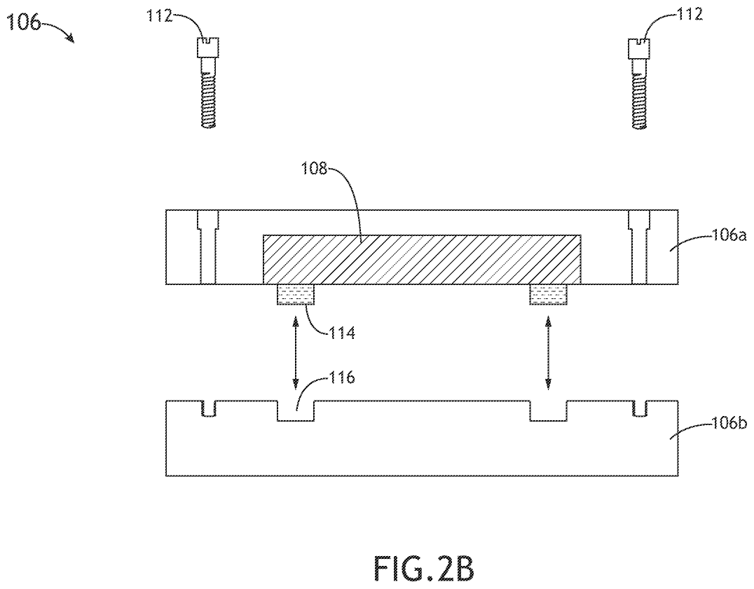

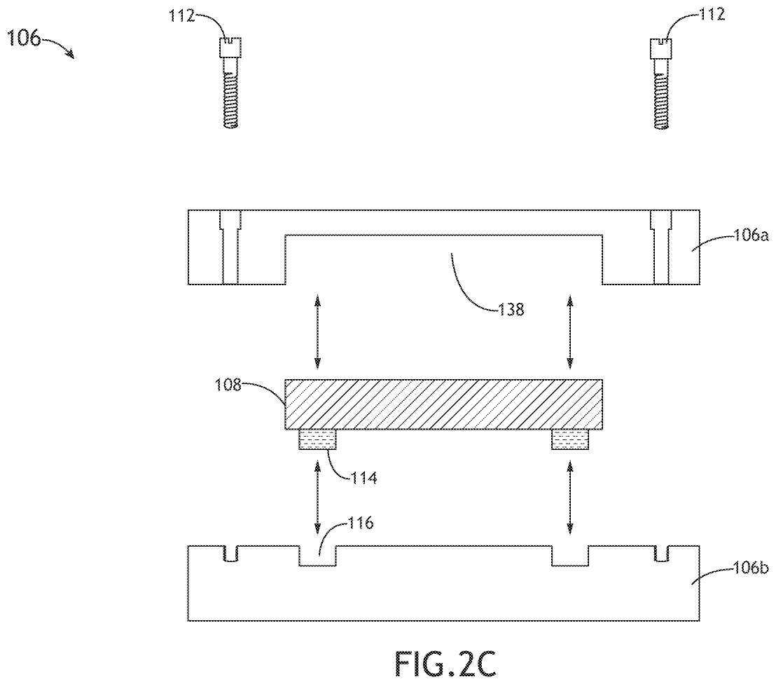

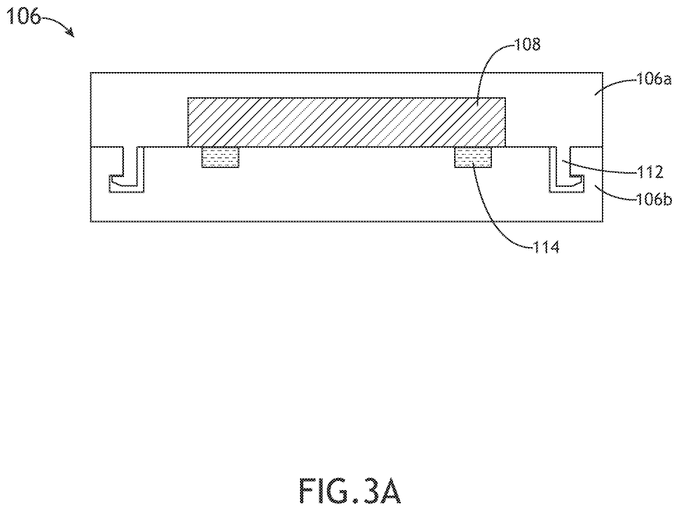

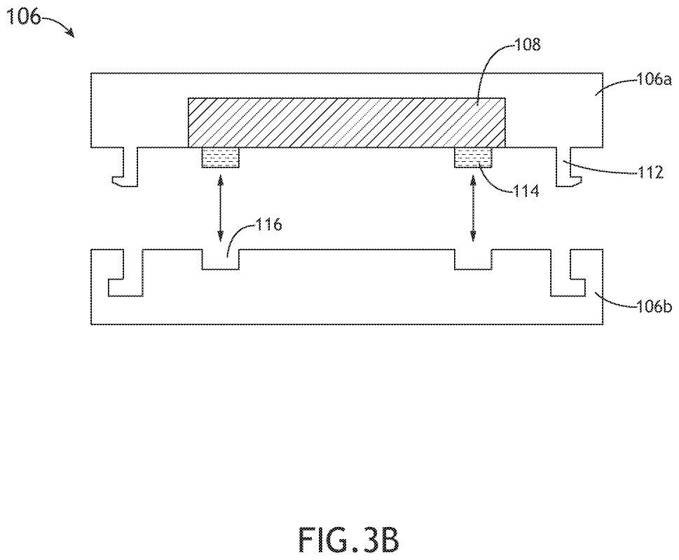

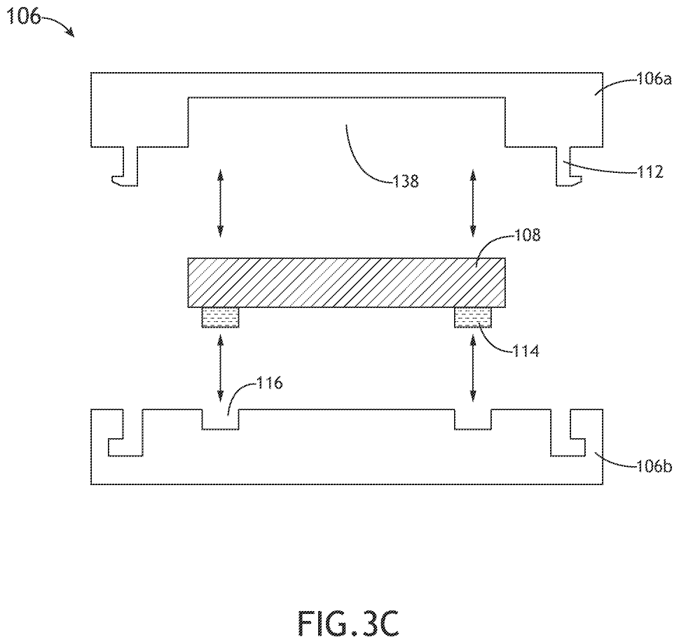

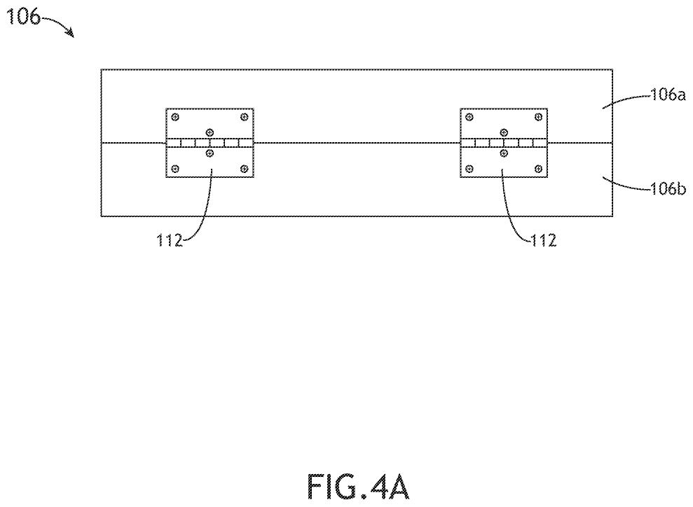

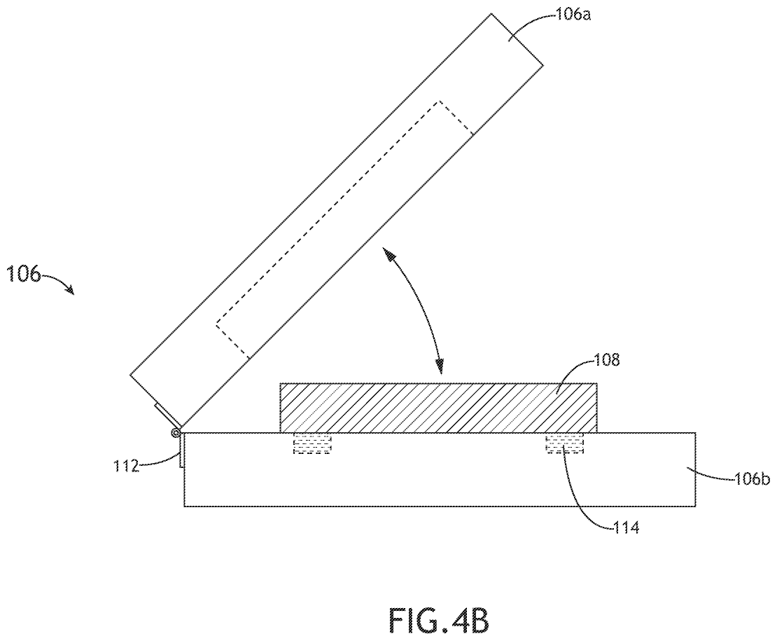

FIGS. 2A-3C illustrate simplified cross-sectional views of the enclosure assembly 106, in accordance with one or more embodiments of the present disclosure. FIGS. 2A-2C illustrate the enclosure assembly 106 with one or more fasteners 112 (e.g., one or more screws), in accordance with one or more embodiments of the present disclosure. FIGS. 3A-3C illustrate the enclosure assembly 106 with a snap-fit assembly 112, in accordance with one or more embodiments of the present disclosure. FIGS. 2B-2C and 3B-3C illustrate exploded cross-sectional views of the enclosure assembly 106 and the electronics assembly 108, in accordance with one or more embodiments of the present disclosure. FIGS. 4A-4B illustrate simplified rear and side views, respectively, of the enclosure assembly 106 with a hinge assembly 112, in accordance with one or more embodiments of the present disclosure.

In one embodiment, the enclosure assembly 106 includes a top portion 106a and a bottom portion 106b. For example, the enclosure assembly 106 may include a top portion 106a configured to detachably connect to a bottom portion 106b. For instance, the enclosure assembly 106 may include one or more coupling devices 112 configured to detachably connect the top portion 106a and the bottom portion 106b such that the top portion 106a and the bottom portion 106b are mechanically coupled. For purposes of the present disclosure the terms “detachably connectable” may be interpreted such that the top portion 106a and the bottom portion 106b may be separate portions that are configured to couple together via the coupling devices 112 to form the enclosure assembly 106, as shown in FIGS. 2B-2C and FIGS. 3B-3C.

It is noted herein that the one or more coupling devices 112 may include any coupling device known in the art. For example, the one or more coupling devices 112 may include one or more fasteners. For instance, the one or more coupling devices 112 may include, but are not required to include, one or more screws, one or more bolts, or the like. In this regard, as shown in FIGS. 2A-2C, the top portion 106a and the bottom portion 106b may include one or more holes configured to receive a portion of the one or more fasteners. By way of another example, as shown in FIGS. 3A-3C, the one or more coupling devices 112 may include a snap-fit assembly. For instance, the one or more coupling devices 112 may include a snap-fit assembly including a protrusion and a mating part with a depression. In this regard, the protrusion may be configured to catch the depression of the mating part on the bottom portion 106b, such that the top portion 106a and the bottom portion 106b are mechanically coupled. By way of another example, as shown in FIGS. 4A-4B, the one or more coupling devices 112 may include a hinge assembly. For instance, the one or more coupling devices 112 may include a hinge assembly including, but not limited to, one or more leaves (e.g., a leaf for the top portion and leaf for the bottom portion), one or more pins, one or more knuckles, one or more fastener holes, and one or more fasteners. In this regard, the top portion 106a and the bottom portion 106b may be mechanically coupled to the top leaf and the bottom leaf, respectively, via the one or more fasteners, such that the top portion 106a and the bottom portion 106b are mechanically coupled.

In another embodiment, the top portion 106a is configured to be electrically coupled to the bottom portion 106b. For example, as shown in FIGS. 2B-2C and FIGS. 3B-3C, the top portion 106a may be reversibly, electrically coupled to the bottom portion 106b via one or more electrical contacts 114. For instance, the top portion 106a may be reversibly, electrically coupled to the bottom portion 106b via one or more pogo pins (e.g., spring-loaded pogo pins). In this regard, the top portion 106a may include a pogo pin 116 and the bottom portion 106b may include a pogo pin connector 118, such that the pogo pin connector 118 may be configured to receive the pogo pin 116. It is noted herein that the top portion 106a may be reversibly, electrically coupled to the bottom portion 106b via any electrical coupling mechanism known in the art. Therefore, the above discussion should be construed as limiting the scope of the present disclosure. For purposes of the present disclosure to term “reversibly, electrically coupled” may be interpreted to mean that when the top portion 106a is mechanically attached to the bottom portion 106b via the one or more coupling devices 112, the one or more electronic contacts 114 electrically couple the top portion 106a and the bottom portion 106b, such that an electrical connection is established between the top portion 106a and the bottom portion 106b.

It is noted herein that coupling devices 112 and/or the electronic contacts 114 of the apparatus 100 may be configured to allow one or more electronic components of the electronic assembly to be easily replaced if the one or more electronic components become damaged (e.g., are exposed to too high of a temperature). For example, as shown in FIGS. 2B and 3B, at least one of the top portion 106a or the bottom portion 106b including the one or more electronic components may be replaced if the one or more electronic components become damaged. In one instance, when the one or more coupling devices 112 include one or more fasteners (e.g., screws), the top portion 106a may be detached from the bottom portion 106b by un-fastening (e.g., unscrewing) the one or more fasteners, such that the detached top portion 106a or bottom portion 106b including the one or more electronic components of the electronic assembly 108 may be removed and replaced. In this regard, a replacement top portion 106a or bottom portion 106b including the one or more electronic components (e.g., replacement electronics) may be mechanically coupled to the bottom portion 106b or top portion 106a, respectively, via the one or more fasteners and electrically coupled via the one or more electronic contacts. In another instance, when the one or more coupling devices 112 include a snap fit assembly, the top portion 106a may be detached from the bottom portion 106b by releasing the protrusion from the depression of the mating part, such that the detached top portion 106a or bottom portion 106b including the one or more electronic components of the electronic assembly 108 may be removed and replaced. In this regard, a replacement top portion 106a or bottom portion 106b including the one or more electronic components (e.g., replacement electronics) may be mechanically coupled to the bottom portion 106b or top portion 106a, respectively, via the snap fit assembly and electrically coupled via the one or more electronic contacts. In a further instance, when the one or more coupling devices 112 include a hinge assembly, the top portion 106a may be detached from the bottom portion 106b by un-fastening at least one leaf of the top portion 106a/bottom portion 106b or removing the pin within the one or more knuckles, such that the detached top portion 106a or bottom portion 106b including the one or more electronic components of the electronic assembly 108 may be removed and replaced. In this regard, a replacement top portion 106a or bottom portion 106b including the one or more electronic components (e.g., replacement electronics) may be mechanically coupled to the bottom portion 106b or top portion 106a, respectively, via the hinge assembly and electrically coupled via the one or more electronic contacts. It is noted herein that when replacing the top portion 106a including the one or more electronic components, one or more components of the coupling devices 112 may also be replaced.

By way of another example, as shown in FIGS. 2C and 3C, the one or more electronic components may be replaced (without replacing the top portion 106a) if the one or more electronic components become damages. In one instance, when the one or more coupling devices 112 include one or more fasteners (e.g., screws), the top portion 106a may be detached from the bottom portion 106b by un-fastening (e.g., unscrewing) the one or more fasteners, such that the one or more electronic components of the electronic assembly 108 may be removed and replaced. In this regard, one or more replacement electronic components may be electrically coupled via the one or more electronic contacts and the top portion 106a and the bottom portion 106b may be mechanically coupled via the one or more fasteners. In another instance, when the one or more coupling devices 112 include a snap fit assembly, the top portion 106a may be detached from the bottom portion 106b by releasing the protrusion from the depression of the mating part, such that the one or more electronic components of the electronic assembly 108 may be removed and replaced. In this regard, one or more replacement electronic components may be electrically coupled via the one or more electronic contacts and the top portion 106a and the bottom portion 106b may be mechanically coupled via the snap fit assembly. In a further instance, as shown in FIG. 4B, when the one or more coupling devices 112 include a hinge assembly, the one or more knuckles and the one or more pins of the hinge assembly may be configured to allow the top portion 106a and the bottom portion 106b to separate a select distance, such that the one or more electronic components of the electronic assembly 108 may be removed and replaced. In this regard, one or more replacement electronic components may be electrically coupled via the one or more electronic contacts and the one or more knuckles and the one or more pins of the hinge assembly may be configured to allow the top portion 106a and the bottom portion 106b to be flush (e.g., closed the select distance). In a further instance, when the one or more coupling devices 112 include a hinge assembly, the top portion 106a may be detached from the bottom portion 106b by un-fastening at least the top leaf of the top portion 106a or removing the pin within the one or more knuckles, such that the one or more electronic components of the electronic assembly 108 may be removed and replaced. In this regard, one or more replacement electronic components may be electrically coupled via the one or more electronic contacts and the top portion 106a and the bottom portion 106b may be mechanically coupled via the hinge assembly.

Further it is noted herein that one or more components of the apparatus may be reused despite one or more of the one or more electronic contacts encountering too high of a temperature by replacing the one or more electronic components, thereby extending the operating parameters (e.g., time and/or temperature) of the apparatus. For example, the power source and/or the one or more processors may be replaced, while the memory may be not be replaced, or vice versa. For instance, the memory may be able to withstand a higher temperature than the power source and/or the one or more processors, such that the memory may not become damaged if exposed to a temperature that damages the one or more processors and/or the memory, and vice versa.

It is noted herein that the enclosure assembly 106 may be formed of any material known in the art. For example, the enclosure assembly 106 may be formed from one or more materials including, but not limited to, a ceramic, a composite, a glass, or the like. By way of another example, the enclosure assembly 106 may be formed from a material causing negligible contamination. For instance, the enclosure assembly 106 may be formed from one or more low contamination materials such as, but not limited to, silicon, silicon carbide, silicon nitride, silicon oxide, or the like.

In one embodiment, the one or more electronic components of the electronic assembly 108 are disposed within the enclosure assembly 106. For example, the top portion 106a may at least partially embed the one or more electronic components of the electronic assembly 108. For instance, as shown in FIGS. 2B and 3B, the top portion 106a may at least partially embed the one or more electronic components of the electronic assembly 108. In this regard, the one or more electronic components of the electronic assembly 108 may be welded, bonded, or the like to the top portion 106a of the enclosure assembly 106. Further, if the one or more electronic components of the electronic assembly 108 are damaged, then the top portion 106a including the electronic components may be easily replaced if the one or more electronic components are damaged (e.g., exposed to high temperature). By way of another example, the bottom portion 106b may at least partially embed the one or more electronic components of the electronic assembly 108. For instance, the bottom portion 106b may at least partially embed the one or more electronic components of the electronic assembly 108. In this regard, the one or more electronic components of the electronic assembly 108 may be welded, bonded, or the like to the bottom portion 106b of the enclosure assembly 106. Further, if the one or more electronic components of the electronic assembly 108 are damaged, then the bottom portion 106b including the electronic components may be easily replaced if the one or more electronic components are damaged (e.g., exposed to high temperature).

By way of another example, as shown in FIGS. 2C and 3C, the one or more electronic components of the electronic assembly 108 may be separate from the top portion 106a and the bottom portion 106b. For instance, the one or more electronic components of the electronic assembly 108 may be detachably connectable to the top portion 106a and/or the bottom portion 106b, such that the one or more electronic components may be easily replaced if damaged (e.g., exposed to too high of a temperature). In this regard, the one or more electronic components of the electronic assembly 108 may fit within a cavity 138 of the top portion 106a. In another regard, the one or more electronic components of the electronic assembly 108 may fit within a cavity of the bottom portion 106b.

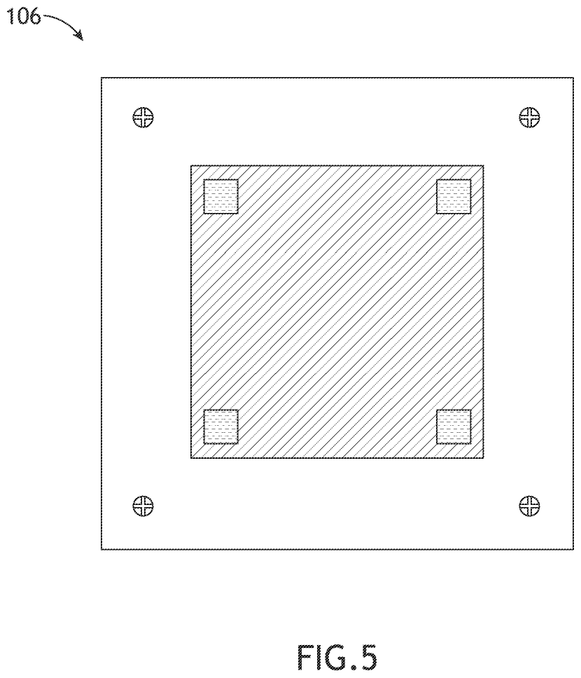

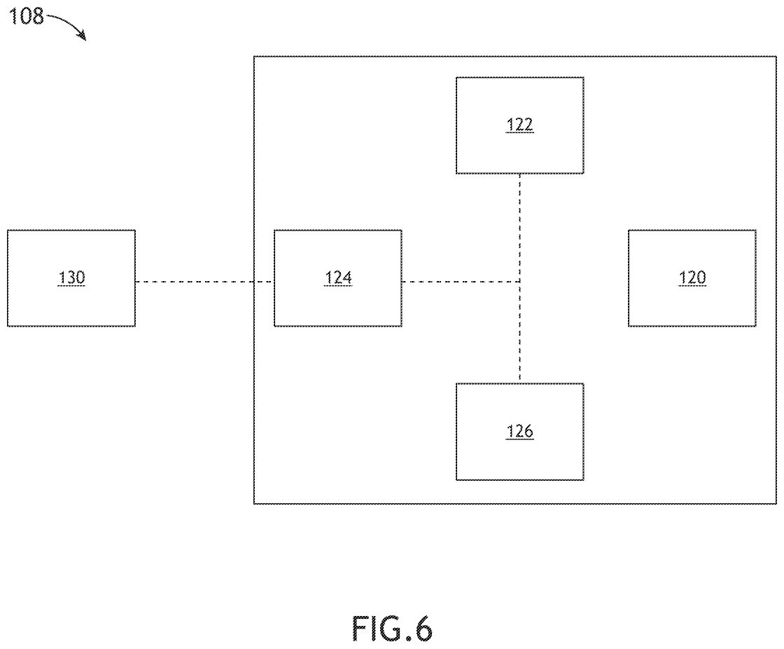

FIG. 5 illustrates a simplified top view of the electronic assembly 108 contained within the enclosure assembly 106, in accordance with one or more embodiments of the present disclosure. FIG. 6 illustrates a simplified block diagram of one or more electronic components of the electronic assembly 108, in accordance with one or more embodiments of the present disclosure.

In one embodiment, the electronic assembly 108 includes one or more electronic components. In another embodiment, the one or more electronic components of the electronic assembly 108 include a power source 120. The electronic assembly 108 may include any type of power source known in the art. For example, the electronic assembly 108 may include one or more batteries. For instance, the electronic assembly 108 may include one or more coin cell batteries. In some embodiments, the power source 120 may be housed in a housing. For example, the power source 120 may be housed in a metal housing within the enclosure assembly 106.

In another embodiment, the one or more electronic components of the electronic assembly 108 include one or more processors 122. For example, the one or more processors 122 may be configured to receive one or more measurement parameters from the one or more sensors 110 of the sensor assembly 104. In another embodiment, the one or more electronic components of the electronic assembly 108 include communication circuitry 124. In another embodiment, the one or more electronic components of the electronic assembly 108 include a memory medium 126 (e.g., memory) for storing the program instructions for the one or more processors 122 and/or the measurement parameters received from the one or more sensors 110.

It is noted herein that the one or more electronic components of the electronic assembly 108 may include any electronic component known in the art including, but not limited to, an analog-to-digital converter.

In another embodiment, the electronic assembly 108 is communicatively coupled to a remote data system 130. In another embodiment the electronic assembly 108 transmits a plurality of measurement parameters to the remote data system 130.

The one or more processors 122 may include any processor or processing element known in the art. For the purposes of the present disclosure, the term “processor” or “processing element” may be broadly defined to encompass any device having one or more processing or logic elements. In this sense, the one or more processors 122 may include any device configured to execute algorithms and/or instructions (e.g., program instructions stored in memory). It should be recognized that the steps described throughout the present disclosure may be carried out by a single processor or, alternatively, multiple processors.

The memory medium 126 may include any storage medium known in the art suitable for storing program instructions executable by the associated one or more processors 122. For example, the memory medium 126 may include a non-transitory memory medium. By way of another example, the memory medium 126 may include, but is not limited to, a read-only memory (ROM), a random-access memory (RAM), a solid-state drive, and the like. It is further noted that memory medium 126 may be housed in a common controller housing with the one or more processors 122. In one embodiment, the memory medium 126 may be located remotely with respect to the physical location of the one or more processors 122. For instance, the one or more processors 122 may access a remote memory (e.g., server), accessible through a network (e.g., internet, intranet and the like).

In one embodiment, the sensor assembly 104 is communicatively coupled to the electronic assembly 108. For example, the sensor assembly 104 may be coupled to the electronic assembly 108 via one or more wired connections (e.g., wires, interconnects, or the like). In another embodiment, the one or more electronic components of the electronic assembly 108 may be configured to acquire one or more measurement parameters from the sensor assembly 104. For instance, the one or more processors 122 of the electronic assembly 108 may acquire one or more measurement parameters from the one or more sensors 110 of the sensor assembly 104. The one or more measurement parameters may include, but are not limited to, voltage (or other signals) from a temperature sensor (e.g., thermocouple)voltage (or other signals) from a pressure sensor, voltage (or other signals) from a radiation sensor, voltage (or other signals) from a chemical sensor and the like indicative of values from the one or more sensors 110 located at one or more locations on the substrate 102.

In another embodiment, the apparatus 100 includes one or more support structures 132 configured to support the enclosure assembly 106 (including the electronic assembly 108) on the substrate 102. For example, the one or more support structures 132 may include, but are not limited to, one or more legs (e.g., single support leg or multiple support legs). The one or more support structures 132 may be formed from a material having a low thermal conductivity coefficient so as to limit the heat transfer between the enclosure assembly 106 and the substrate 102. For example, the one or more support structures 132 may be formed from a low thermal conductivity material such as, but not limited to, a ceramic, a composite, a crystalline material, glass, or the like. For instance, the one or more support structures 132 may be formed from a low thermal conductivity material such as, but not limited to, silicon nitride, silicon oxide, or the like.

In another embodiment, the enclosure assembly 106 and the substrate 102 may be coupled together via one or more fasteners. For example, the enclosure assembly 106 may be directly fastened (e.g., screwed, or bolted) to a portion of the substrate 102. By way of another example, the enclosure assembly 106 may be coupled to the substrate 102 via one or more adhesives. In another embodiment, the enclosure assembly 106 is integrated within the substrate 102. For example, the enclosure assembly 106 may be partially embedded within the substrate 102. For instance, the enclosure assembly 106 may be coated with a thermal coating to prevent heat transfer (e.g., a material having a low thermal conductivity coefficient).

In another embodiment, the enclosure assembly 106 includes an insulating medium 134 within a cavity 136 between the enclosure assembly 106 and the electronic assembly 108. It is noted that the implementation of an insulating medium 134 between the enclosure assembly 106 and the electronic assembly 108 serves to reduce heat transfer from the elevated temperature environment (e.g., semiconductor processing chamber) outside of the enclosure assembly 106 to the electronic assembly 108. In another embodiment, the insulating medium 134 may include, but is not limited to, a porous solid material. For example, the insulating medium 134 may be one or more aerogel materials (e.g., silica aerogel material). For instance, an aerogel material can be formed with a porosity as high as approximately 98.5%. By way of another example, the insulating medium 134 may be a ceramic material (e.g., porous ceramic material). It is noted herein that during the sintering of a ceramic based insulating medium the porosity may be controlled through the use of pore formers. It is further noted herein that the porosity of a ceramic material may be fabricated with a porosity range of 50-99%. For example, the porosity of a ceramic material may be fabricated to have a porosity range between 95-99%.

In another embodiment, the insulating medium 134 is opaque. For example, the insulating medium 134 may include, but is not limited to, a material that is absorptive of radiation traversing the volume between the enclosure assembly 106 and the electronic assembly 108. For instance, the insulating medium 134 may include, but is not limited to, a carbon-doped aerogel material.

In another embodiment, the insulating medium 134 is low pressure gas (i.e., gas held at vacuum pressure), whereby the gas is maintained at a pressure less than ambient pressure (i.e., pressure of process chamber). In this regard, the volume between the enclosure assembly 106 and the electronic assembly 108 may be maintained at a vacuum pressure so as to minimize heat conduction from the enclosure assembly 106 and the electronic assembly 108. In another embodiment, the insulating medium 134 is a gas maintained at pressure approximately equal to ambient pressure, but less than atmospheric pressure. In another embodiment, the insulating medium 134 is a gas maintained at pressure higher than ambient pressure, but less than atmospheric pressure. For the purposes of the present disclosure, “vacuum pressure” is interpreted to mean any pressure that is lower than ambient pressure.

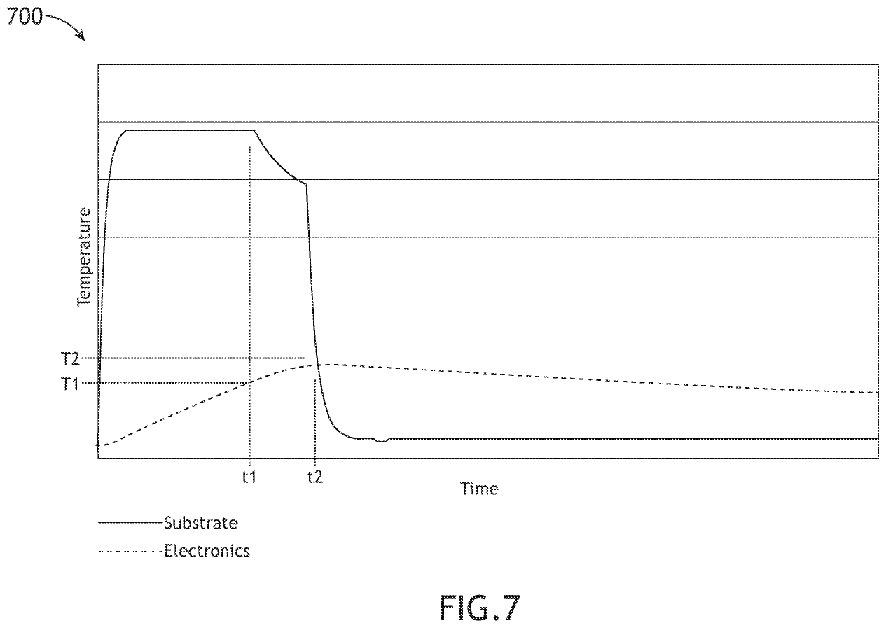

FIG. 7 is a time-temperature plot 700 illustrating data collection of a process condition sensing apparatus, in accordance with one or more embodiments of the present disclosure.

As shown in FIG. 7, the crucial data collection only occurs until time t1, which is the time the substrate is removed from the heating source. At this point (t1) the electronics are at temperature T1. The one or more electronic components of the electronic assembly 108 continue to heat until temperature T2 (at time t2). Between time t1 and t2 the collection of data is not as critical. In one embodiment, data collection or other functions are terminated at t1 in order to minimize the damage to one or more electronics of the electronic assembly 108.

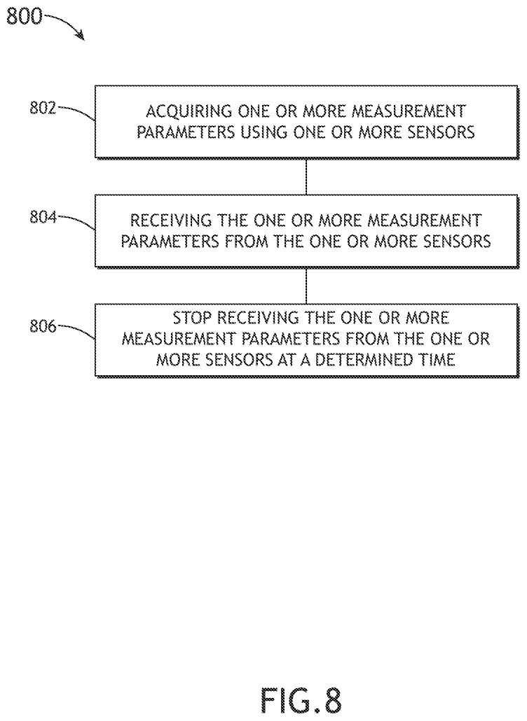

FIG. 8 illustrates a flowchart of a method 800 for extending the operating parameters of a process condition sensing apparatus (e.g., process condition sensing apparatus 100), in accordance with one or more embodiments of the present disclosure. It is noted herein that the steps of method 800 may be implemented all or in part by apparatus 100. It is further recognized, however, that the method 800 is not limited to the apparatus 100 in that additional or alternative apparatus-level embodiments may carry out all or part of the steps of method 800.

In step 802, one or more measurement parameters are acquired using one or more sensors of a sensor assembly. For example, the substrate 102 may include one or more sensors 110 of a sensor assembly 104 disposed on the substrate 102 at one or more locations across the substrate 102. For instance, the one or more sensors 110 disposed at one or more locations across the substrate 102 may be configured to acquire one or more measurement parameters from the one or more locations across the substrate 102. It is noted that the one or more sensors 110 may include any measurement device known in the art including, but not limited to, one or more temperature sensors, one or more pressure sensors, one or more radiation sensors, one or more chemical sensors, or the like. For instance, the one or more temperature sensors may include, but are not limited to, one or more thermocouple (TC) devices (e.g., thermoelectric junction), one or more resistance temperature devices (RTDs) (e.g., thin film RTD), or the like. In another instance, in the case of pressure measurements, the one or more sensors 110 may include, but are not limited to, a piezoelectric sensor, a capacitive sensor, an optical sensor, a potentiometric sensor and the like. In another instance, in the case of radiation measurements, the one or more sensors 110 may include, but are not limited to, one or more light detectors (e.g., photovoltaic cell, photoresistor and the like) or other radiation detectors (e.g., solid state detector). In another instance, in the case of chemical measurements, the one or more sensors 110 may include, but are not limited to, one or more chemiresistors, gas sensors, pH sensors, and the like.

In step 804, the one or more measurement parameters from the one or more sensors are received by one or more electronic components of the electronic assembly within the enclosure assembly. For example, the one or more processors 122 of the electronic assembly 108 may be configured to receive the one or more measurement parameters from the one or more sensors 110 disposed on the substrate 102. For instance, the one or more processors 122 may be configured to receive the one or more measurement parameters from the one or more sensors 110 at one or more locations across the substate 104. The one or more measurement parameters may include, but are not limited to, voltage from thermocouples, resistance from resistance temperature devices, voltage (or other signals) from a pressure sensor, voltage (or other signals) from a radiation sensor, voltage (or other signals) from a chemical sensor and the like) indicative of values from the one or more sensors 110 located at one or more locations on the substrate 102.

In step 806, one or more control signals are generated at a determined time to switch the operating conditions of the one or more electronic components of the electronic assembly. For example, at the determined time, the one or more electronic components may be configured to stop receiving the one or more measurement parameters from the one or more sensors. For instance, the one or more controls signals may be generated when the substrate 102 is removed from a heat source. In another instance, the one or more control signals may be generated when at least one of the one or more electronic components of the electronic assembly 108 reach a critical temperature. The critical temperature of the at least one of the one or more electronic components of the electronic assembly 108 may be a temperate that causes the at least one of the one or more electronic components to become damaged. In this regard, as shown in FIG. 7, the one or more processors 122 of the electronic assembly 108 may be configured to stop receiving the one or more measurement parameters from the one or more sensors 110 at t1 (e.g., when data collection is not as critical) or when a critical temperature is reached. It is noted herein that by not receiving the one or more measurement parameters at t1, the operating parameters of the apparatus may be extended.

One skilled in the art will recognize that the herein described components, devices, objects, and the discussion accompanying them are used as examples for the sake of conceptual clarity and that various configuration modifications are contemplated. Consequently, as used herein, the specific exemplars set forth and the accompanying discussion are intended to be representative of their more general classes. In general, use of any specific exemplar is intended to be representative of its class, and the non-inclusion of specific components, devices, and objects should not be taken as limiting.

Those having skill in the art will appreciate that there are various vehicles by which processes and/or systems and/or other technologies described herein can be effected (e.g., hardware, software, and/or firmware), and that the preferred vehicle will vary with the context in which the processes and/or systems and/or other technologies are deployed. For example, if an implementer determines that speed and accuracy are paramount, the implementer may opt for a mainly hardware and/or firmware vehicle; alternatively, if flexibility is paramount, the implementer may opt for a mainly software implementation; or, yet again alternatively, the implementer may opt for some combination of hardware, software, and/or firmware. Hence, there are several possible vehicles by which the processes and/or devices and/or other technologies described herein may be effected, none of which is inherently superior to the other in that any vehicle to be utilized is a choice dependent upon the context in which the vehicle will be deployed and the specific concerns (e.g., speed, flexibility, or predictability) of the implementer, any of which may vary.

The previous description is presented to enable one of ordinary skill in the art to make and use the invention as provided in the context of a particular application and its requirements. As used herein, directional terms such as “top,” “bottom,” “over,” “under,” “upper,” “upward,” “lower,” “down,” and “downward” are intended to provide relative positions for purposes of description, and are not intended to designate an absolute frame of reference. Various modifications to the described embodiments will be apparent to those with skill in the art, and the general principles defined herein may be applied to other embodiments. Therefore, the present invention is not intended to be limited to the particular embodiments shown and described, but is to be accorded the widest scope consistent with the principles and novel features herein disclosed.

With respect to the use of substantially any plural and/or singular terms herein, those having skill in the art can translate from the plural to the singular and/or from the singular to the plural as is appropriate to the context and/or application. The various singular/plural permutations are not expressly set forth herein for sake of clarity.

All of the methods described herein may include storing results of one or more steps of the method embodiments in memory. The results may include any of the results described herein and may be stored in any manner known in the art. The memory may include any memory described herein or any other suitable storage medium known in the art. After the results have been stored, the results can be accessed in the memory and used by any of the method or system embodiments described herein, formatted for display to a user, used by another software module, method, or system, and the like. Furthermore, the results may be stored “permanently,” “semi-permanently,” temporarily,” or for some period of time. For example, the memory may be random access memory (RAM), and the results may not necessarily persist indefinitely in the memory.

It is further contemplated that each of the embodiments of the method described above may include any other step(s) of any other method(s) described herein. In addition, each of the embodiments of the method described above may be performed by any of the systems described herein.

The herein described subject matter sometimes illustrates different components contained within, or connected with, other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “connected,” or “coupled,” to each other to achieve the desired functionality, and any two components capable of being so associated can also be viewed as being “couplable,” to each other to achieve the desired functionality. Specific examples of couplable include but are not limited to physically mateable and/or physically interacting components and/or wirelessly interactable and/or wirelessly interacting components and/or logically interacting and/or logically interactable components.

Furthermore, it is to be understood that the invention is defined by the appended claims. It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” and the like). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to inventions containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations). Furthermore, in those instances where a convention analogous to “at least one of A, B, and C, and the like” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, and the like). In those instances where a convention analogous to “at least one of A, B, or C, and the like” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, and the like). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

It is believed that the present disclosure and many of its attendant advantages will be understood by the foregoing description, and it will be apparent that various changes may be made in the form, construction and arrangement of the components without departing from the disclosed subject matter or without sacrificing all of its material advantages. The form described is merely explanatory, and it is the intention of the following claims to encompass and include such changes. Furthermore, it is to be understood that the invention is defined by the appended claims.

What is claimed:

1. A process condition sensing apparatus, comprising:
a substrate;
an electronic assembly, wherein the electronic assembly includes one or more electronic components;
an enclosure assembly, wherein the enclosure assembly comprises a top portion and a bottom portion, wherein the top portion is detachably connectable to the bottom portion via one or more coupling devices, wherein the top portion is reversibly, electrically couplable to the bottom portion via one or more electronic contacts, wherein the one or more electronic components of the electronic assembly are disposed within the enclosure assembly; and
a sensor assembly communicatively coupled to the electronic assembly, wherein the sensor assembly includes one or more sensors disposed on the substrate at one or more locations across the substrate, wherein the one or more sensors are configured to acquire one or more measurement parameters at the one or more locations across the substrate.

2. The apparatus of claim 1, wherein the one or more electronic components are at least partially embedded within the top portion of the enclosure assembly.

3. The apparatus of claim 1, wherein the one or more electronic components are at least partially embedded within the bottom portion of the enclosure assembly.

4. The apparatus of claim 1, wherein the one or more electronic components are detachably connectable to the top portion of the enclosure assembly.

5. The apparatus of claim 1, wherein the one or more electronic components are detachably connectable to the bottom portion of the enclosure assembly.

6. The apparatus of claim 1, wherein the one or more electronic contacts include one or more pogo pins.

7. The apparatus of claim 1, wherein the one or more electronic components of the electronic assembly comprise:
one or more processors, wherein the one or more processors are configured to receive the one or more measurement parameters from the one or more sensors;
communication circuitry;
memory; and
a power source.

8. The apparatus of claim 7, wherein the one or more processors of the electronic assembly stop receiving the one or more measurement parameters from the one or more sensors at a determined time.

9. The apparatus of claim 8, wherein the determined time is the time at which the substrate is removed from a heating source.

10. The apparatus of claim 8, wherein the determined time is the time at which at least one of the one or more electronic components of the electronic assembly reach a critical temperature.

11. The apparatus of claim 1, wherein the one or more coupling devices include one or more fasteners.

12. The apparatus of claim 11, wherein the one or more fasteners include at least one of:
a screw or a bolt.

13. The apparatus of claim 1, wherein the one or more coupling devices includes a snap fit assembly, wherein the snap fit assembly includes a protrusion and a mating part including a depression, wherein the protrusion is configured to catch the depression of the mating part.

14. The apparatus of claim 1, wherein the one or more coupling devices includes a hinge assembly.

15. The apparatus of claim 1, further comprising:
an insulating medium disposed within a cavity between the enclosure assembly and the electronic assembly.

16. The apparatus of claim 1, further comprising:
one or more support structures for supporting the electronic assembly on the substrate.

17. An enclosure assembly, comprising:
a top portion; and
a bottom portion,
wherein the top portion is detachably connectable to the bottom portion via one or more coupling devices, wherein the top portion is reversibly, electrically couplable to the bottom portion via one or more electronic contacts, wherein one or more electronic components are disposed within the enclosure assembly.

18. The enclosure assembly of claim 17, wherein the one or more electronic components are at least partially embedded within the top portion.

19. The enclosure assembly of claim 17, wherein the one or more electronic components are at least partially embedded within the bottom portion.

20. The enclosure assembly of claim 17, wherein the one or more electronic components are detachably connectable to the top portion.

21. The enclosure assembly of claim 17, wherein the one or more electronic components are detachably connectable to the bottom portion.

22. The enclosure assembly of claim 17, wherein the one or more electronic contacts include one or more pogo pins.

23. The enclosure assembly of claim 17, wherein the one or more coupling devices include one or more fasteners.

24. The enclosure assembly of claim 23, wherein the one or more fasteners include at least one of:
a screw or a bolt.

25. The enclosure assembly of claim 17, wherein the one or more coupling devices includes a snap fit assembly, wherein the snap fit assembly includes a protrusion and a mating part including a depression, wherein the protrusion is configured to catch the depression of the mating part.

26. The enclosure assembly of claim 17, wherein the one or more coupling devices includes a hinge assembly.

27. The enclosure assembly of claim 17, wherein the one or more electronic components comprise:
one or more processors, wherein the one or more processors are configured to receive one or more measurement parameters from one or more sensors disposed on a substrate at one or more locations across the substrate, wherein the one or more sensors are configured to acquire one or more measurement parameters at the one or more locations across the substrate;
communication circuitry;
memory; and
a power source.

28. The enclosure assembly of claim 27, wherein the one or more processors stop receiving the one or more measurement parameters from the one or more sensors at a determined time.

29. The enclosure assembly of claim 28, wherein the determined time is the time at which the substrate is removed from a heating source.

30. The enclosure assembly of claim 28, wherein the determined time is the time at which at least one of the one or more electronic components reach a critical temperature.

31. The enclosure assembly of claim 17, further comprising an insulating medium, wherein the insulating medium is disposed within a cavity between the enclosure assembly and the one or more electronic components.

32. A process condition sensing apparatus, comprising:
a substrate;
an electronic assembly, wherein the electronic assembly includes one or more electronic components, wherein the one or more electronic components comprise:
one or more processors;
communication circuitry;
memory; and
a power source;
an enclosure assembly, wherein the enclosure assembly comprises a top portion and a bottom portion, wherein the top portion is detachably connectable to the bottom portion via one or more coupling devices, wherein the top portion is reversibly, electrically couplable to the bottom portion via one or more electronic contacts, wherein the one or more electronic components of the electronic assembly are disposed within the enclosure assembly; and
a sensor assembly communicatively coupled to the electronic assembly, wherein the sensor assembly includes one or more sensors disposed on the substrate at one or more locations across the substrate, wherein the one or more sensors are configured to acquire one or more measurement parameters at the one or more locations across the substrate, wherein the one or more processors are configured to receive the one or more measurement parameters from the one or more sensors, wherein the one or more processors are configured to stop receiving the one or more measurement parameters from the one or more sensors at a determined time.

33. The apparatus of claim 32, wherein the one or more electronic components are at least partially embedded within the top portion of the enclosure assembly.

34. The apparatus of claim 32, wherein the one or more electronic components are at least partially embedded within the bottom portion of the enclosure assembly.

35. The apparatus of claim 32, wherein the one or more electronic components are detachably connectable to the top portion of the enclosure assembly.

36. The apparatus of claim 32, wherein the one or more electronic components are detachably connectable to the bottom portion of the enclosure assembly.

37. The apparatus of claim 32, wherein the one or more electronic contacts include one or more pogo pins.

38. The apparatus of claim 32, wherein the determined time is the time at which the substrate is removed from a heating source.

39. The apparatus of claim 32, wherein the determined time is the time at which at least one of the one or more electronic components of the electronic assembly reach a critical temperature.

40. The apparatus of claim 32, wherein the one or more coupling devices include one or more fasteners.

41. The apparatus of claim 40, wherein the one or more fasteners include at least one of:
a screw or a bolt.

42. The apparatus of claim 32, wherein the one or more coupling devices includes a snap fit assembly, wherein the snap fit assembly includes a protrusion and a mating part including a depression, wherein the protrusion is configured to catch the depression of the mating part.

43. The apparatus of claim 32, wherein the one or more coupling devices includes a hinge assembly.

44. A method, comprising:
acquiring one or more measurement parameters using one or more sensors disposed on a substrate at one or more locations across the substrate;
receiving the one or more measurement parameters from the one or more sensors using one or more electronic components of an electronic assembly within an enclosure assembly, wherein the enclosure assembly comprises a top portion and a bottom portion, wherein the top portion is detachably connectable to the bottom portion via one or more coupling devices, wherein the top portion is reversibly, electrically couplable to the bottom portion via one or more electronic contacts; and
generating one or more control signals at a determined time to switch the operating conditions of the one or more electronic components of the electronic assembly, wherein after the determined time the one or more electronic components of the electronic assembly stop receiving the one or more measurement parameters from the one or more sensors.

45. The method of claim 44, wherein the one or more electronic contacts include one or more pogo pins.

46. The method of claim 44, wherein the determined time is the time at which the substrate is removed from a heating source.

47. The method of claim 44, wherein the one or more electronic components comprise:
one or more processors;
communication circuitry;
memory; and
a power source.

48. The method of claim 47, wherein the determined time is the time at which at least one of the one or more electronic components of the electronics assembly reach a critical temperature.
